(19) United States
(12) Patent Application Publication
(10) Pub. No.: US 2024/0249915 A1
(43) Pub. Date: Jul. 25, 2024

(54) PLASMA EXCITATION WITH ION ENERGY CONTROL

(71) Applicant: Applied Materials, Inc., Santa Clara, CA (US)

(72) Inventors: Yang YANG, San Diego, CA (US); Yue GUO, Redwood City, CA (US); Kartik RAMASWAMY, San Jose, CA (US)

(21) Appl. No.: 18/628,009

(22) Filed: Apr. 5, 2024

Related U.S. Application Data
(63) Continuation of application No. 17/337,146, filed on Jun. 2, 2021, now Pat. No. 11,967,483.

(51) Int. Cl. H01J 37/32; H03H 7/01

(52) U.S. Cl. CPC H01J 37/32146; H03H 7/0115; H01J 2237/327

(57) ABSTRACT

Embodiments provided herein generally include apparatus, plasma processing systems and methods for generation of a waveform for plasma processing of a substrate in a processing chamber. One embodiment includes a waveform generator having a voltage source selectively coupled to an output node, where the output node is configured to be coupled to an electrode disposed within a processing chamber, and where the output node is selectively coupled to a ground node. The waveform generator may also include a radio frequency (RF) signal generator, and a first filter coupled between the RF signal generator and the output node.

### CROSS-REFERENCE TO RELATED APPLICATIONS

This application is a continuation of co-pending U.S. patent application Ser. No. 17/337,146, filed Jun. 2, 2021, which is herein incorporated by reference in its entirety.

### BACKGROUND

### Field

Embodiments of the present disclosure generally relate to a system used in semiconductor device manufacturing. More specifically, embodiments of the present disclosure relate to a plasma processing system used to process a substrate.

### Description of the Related Art

Reliably producing high aspect ratio features is one of the key technology challenges for the next generation of semiconductor devices. One method of forming high aspect ratio features uses a plasma-assisted etching process in which a plasma is formed in a processing chamber and ions from the plasma are accelerated towards a surface of a substrate to form openings in a material layer disposed beneath a mask layer formed on the surface of the substrate.

In a typical plasma-assisted etching process, the substrate is positioned on a substrate support disposed in a processing chamber, a plasma is formed over the substrate, and ions are accelerated from the plasma towards the substrate across a plasma sheath, i.e., region depleted of electrons, formed between the plasma and the surface of the substrate.

It has been found that conventional RF plasma-assisted etching processes, which only deliver sinusoidal waveform containing RF signals to one or more of the electrodes in a plasma processing chamber, do not adequately or desirably control the sheath properties and generated ion energies, which leads to undesirable plasma processing results. The undesirable processing results can include excessive sputtering of the mask layer and the generation of sidewall defects in high-aspect ratio features.

Accordingly, there is a need in the art for plasma processing and biasing methods that are able to provide desirable plasma-assisted etching process results.

### SUMMARY

Embodiments provided herein generally include apparatus, plasma processing systems and methods for generation of a waveform for plasma processing of a substrate in a processing chamber.

One embodiment of the present disclosure is directed to a waveform generator for plasma processing. The waveform generator generally includes a voltage source selectively coupled to an output node, wherein the output node is configured to be coupled to an electrode disposed within a processing chamber, and wherein the output node is selectively coupled to a ground node, a radio frequency (RF) signal generator, and a first filter coupled between the RF signal generator and the output node.

One embodiment of the present disclosure is directed to a method for waveform generation. The method generally includes coupling a voltage source to an output node during a first phase of a waveform, wherein the output node is coupled to an electrode disposed within a processing chamber, and coupling a ground node to the output node during a second phase of the waveform, wherein a RF signal generator is coupled to the output node through a filter.

One embodiment of the present disclosure is directed to an apparatus for waveform generation. The apparatus generally includes a memory, and one or more processors coupled to the memory. The memory and the one or more processors are configured to: couple a voltage source to an output node during a first phase of a waveform, wherein the output node is coupled to an electrode disposed within a processing chamber; and couple a ground node to the output node during a second phase of the waveform, wherein a RF signal generator is coupled to the output node through a filter.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIG. 1 is a schematic cross-sectional view of a processing system, according to one or more embodiments, configured to practice the methods set forth herein.

FIG. 2A shows a voltage waveform that may be applied to an electrode of a processing chamber, according to one or more embodiments.

FIG. 2B shows a voltage waveform that is established on a substrate due to a voltage waveform applied to an electrode of a processing chamber.

FIG. 3A illustrates a typical ion energy distribution (IED) when using a single frequency excitation waveform.

FIG. 3B is a graph illustrating an IED function (IEDF), in accordance with certain embodiments of the present disclosure.

FIG. 4 illustrates a waveform generated using a waveform generator, in accordance with certain embodiments of the present disclosure.

FIG. 5 illustrates an example implementation of a waveform generator for biasing a substrate to achieve IED control, in accordance with certain aspects of the present disclosure.

FIG. 6 illustrates an example filter topology, in accordance with certain embodiments of the present disclosure.

FIG. 7 is a timing diagram illustrating state of switches of the waveform generator of FIG. 5, in accordance with certain aspects of the present disclosure.

FIG. 8 is a process flow diagram illustrating a method for waveform generation.

### DETAILED DESCRIPTION

With technology node advancing towards 2 nm, fabrication of smaller features with larger aspect ratios involve atomic precision for plasma processing. For etching processes where the plasma ions play an important role, ion energy control is challenging the semiconductor equipment industry. Traditionally RF biased techniques use a sinusoidal wave to excite plasma and accelerate ions.

Some embodiments of the present disclosure are generally directed to techniques for generating a waveform for controlling ion energy distribution (IED). For example, a pulsed voltage waveform and a radio frequency (RF) waveform may be applied to the same node in a plasma chamber to implement a low energy peak and a high-energy peak in the IED function with little to no intermediate energies between the low energy and high energy peaks, as described in more detail herein. Ions associated with the high-energy peak have the energy and directionality to reach to the bottom of a high-aspect ratio feature that is being etched and enable etching reactions. Although ions with low energy cannot reach the bottom of the feature during etching, the low energy ions are still important for etch processes. Ions with intermediate energies are not beneficial for etch processes as they do not have the desired directionality and will hit the sidewall of a feature being etched, often resulting in an undesired bowing of the sidewalls in the etched feature. Some embodiments are directed to techniques for generating a waveform having high energy and low energy peaks, with little to no intermediate energy ions.

### Plasma Processing System Examples

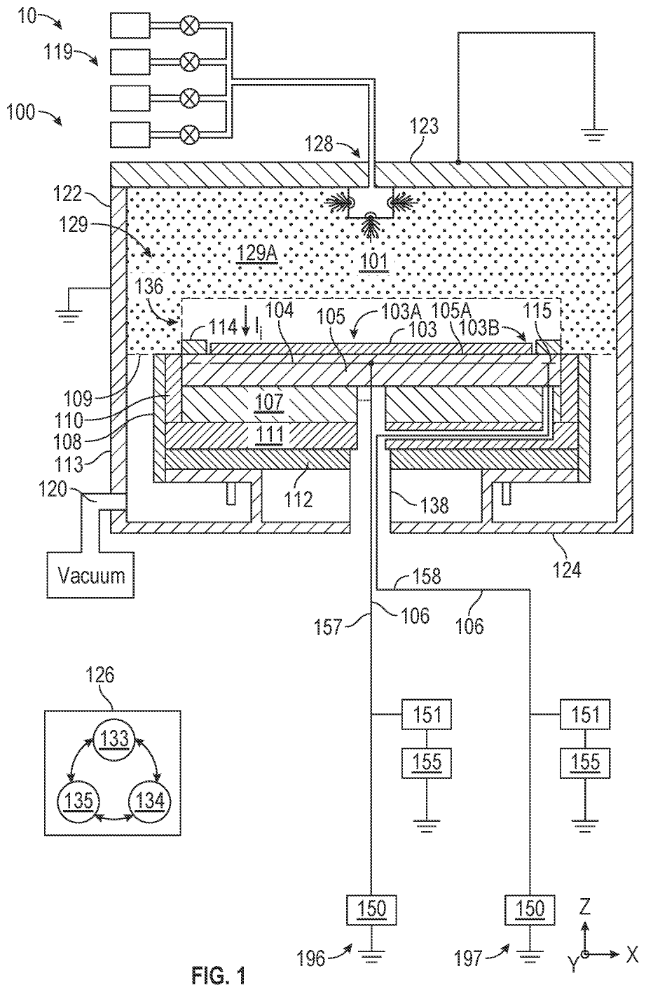

FIG. 1 is a schematic cross-sectional view of a processing system 10 configured to perform one or more of the plasma processing methods set forth herein. In some embodiments, the processing system 10 is configured for plasma-assisted etching processes, such as a reactive ion etch (RIE) plasma processing. However, it should be noted that the embodiments described herein may be also be used with processing systems configured for use in other plasma-assisted processes, such as plasma-enhanced deposition processes, for example, plasma-enhanced chemical vapor deposition (PECVD) processes, plasma-enhanced physical vapor deposition (PEPVD) processes, plasma-enhanced atomic layer deposition (PEALD) processes, plasma treatment processing or plasma-based ion implant processing, for example, plasma doping (PLAD) processing.

As shown, the processing system 10 is configured to form a capacitively coupled plasma (CCP), where the processing chamber 100 include an upper electrode (e.g., chamber lid 123) disposed in a processing volume 129 facing a lower electrode (e.g., the substrate support assembly 136) also disposed in the processing volume 129. In a typical capacitively coupled plasma (CCP) processing system, a radio frequency (RF) source is electrically coupled to one of the upper or lower electrode delivers an RF signal configured to ignite and maintain a plasma (e.g., the plasma 101), which is capacitively coupled to each of the upper and lower electrodes and is disposed in a processing region therebetween. Typically, the opposing one of the upper or lower electrodes is coupled to ground or to a second RF power source for additional plasma excitation. As shown, the processing system 10 includes a processing chamber 100, a support assembly 136, and a system controller 126.

The processing chamber 100 typically includes a chamber body 113 that includes the chamber lid 123, one or more sidewalls 122, and a chamber base 124, which collectively define the processing volume 129. The one or more sidewalls 122 and chamber base 124 generally include materials that are sized and shaped to form the structural support for the elements of the processing chamber 100 and are configured to withstand the pressures and added energy applied to them while a plasma 101 is generated within a vacuum environment maintained in the processing volume 129 of the processing chamber 100 during processing. In one example, the one or more sidewalls 122 and chamber base 124 are formed from a metal, such as aluminum, an aluminum alloy, or a stainless steel alloy.

A gas inlet 128 disposed through the chamber lid 123 is used to deliver one or more processing gases to the processing volume 129 from a processing gas source 119 that is in fluid communication therewith. A substrate 103 is loaded into, and removed from, the processing volume 129 through an opening (not shown) in one of the one or more sidewalls 122, which is sealed with a slit valve (not shown) during plasma processing of the substrate 103.

In some embodiments, a plurality of lift pins 20 movably disposed through openings formed in the substrate support assembly 136 are used to facilitate substrate transfer to and from a substrate supporting surface 105A. In some embodiments, the plurality of lift pins 20 are disposed above and are coupled to and/or are engageable with a lift pin hoop (not shown) disposed in the processing volume 129. The lift pin hoop may be coupled to a shaft (not shown) that sealingly extends through the chamber base 124. The shaft may be coupled to an actuator (not shown) that is used to raise and lower the lift pin hoop. When the lift pin hoop is in a raised position, it engages with the plurality of lift pins 20 to raise the upper surfaces of the lift pins above the substrate supporting surface 105A, lifting the substrate 103 therefrom and enabling access to a non-active (backside) surface the substrate 103 by a robot handler (not shown). When the lift pin hoop is in a lowered position, the plurality of lift pins 20 are flush with or recessed below the substrate supporting surface 105A, and the substrate 103 rests thereon.

The system controller 126, also referred to herein as a processing chamber controller, includes a central processing unit (CPU) 133, a memory 134, and support circuits 135. The system controller 126 is used to control the process sequence used to process the substrate 103, including the substrate biasing methods described herein. The CPU 133 is a general-purpose computer processor configured for use in an industrial setting for controlling the processing chamber and sub-processors related thereto. The memory 134 described herein, which is generally non-volatile memory, may include random access memory, read-only memory, floppy or hard disk drive, or other suitable forms of digital storage, local or remote. The support circuits 135 are conventionally coupled to the CPU 133 and comprise cache, clock circuits, input/output subsystems, power supplies, and the like, and combinations thereof. Software instructions (program) and data can be coded and stored within the memory 134 for instructing a processor within the CPU 133. A software program (or computer instructions) readable by CPU 133 in the system controller 126 determines which tasks are performable by the components in the processing system 10.

Typically, the program, which is readable by CPU 133 in the system controller 126, includes code, which, when executed by the processor (CPU 133), performs tasks relating to the plasma processing schemes described herein. The program may include instructions that are used to control the various hardware and electrical components within the processing system 10 to perform the various process tasks and various process sequences used to implement the methods described herein. In one embodiment, the program includes instructions that are used to perform one or more of the operations described below in relation to FIG. 8.

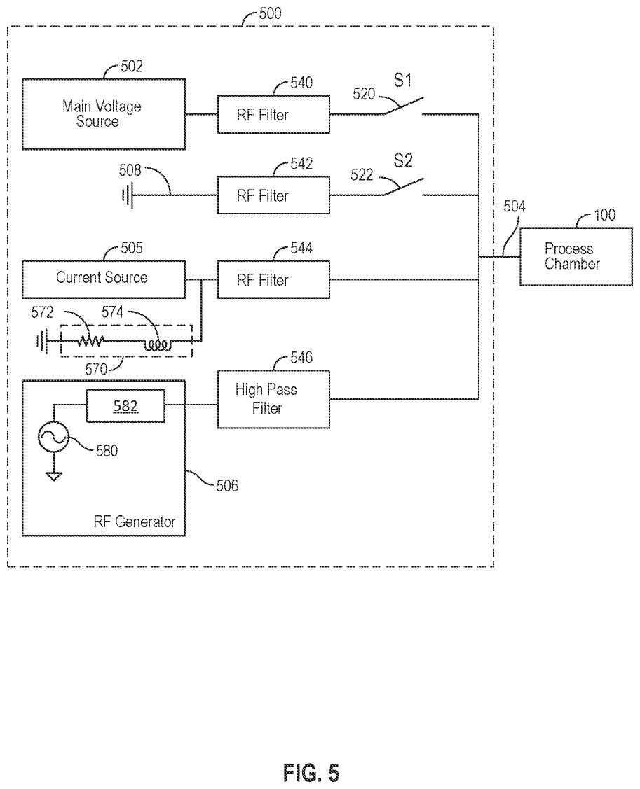

The plasma control system generally includes a first source assembly 196 for establishing at least a first pulsed voltage (PV) waveform at a bias electrode 104, and a second source assembly 197 for establishing at least a second PV waveform at an edge control electrode 115. The first PV waveform or the second PV waveform may be generated using one or more components within a waveform generator assembly 150, which may correspond to a waveform generator as described in more detail herein with respect to FIGS. 4 and 5. In some embodiments, the waveform generator delivers an RF signal to the support base 107 (e.g., power electrode or cathode) or bias electrode 104 which may be used to generate (maintain and/or ignite) a plasma 101 in a processing region disposed between the substrate support assembly 136 and the chamber lid 123.

In some embodiments, the RF signal is used to ignite and maintain a processing plasma 101 using the processing gases disposed in the processing volume 129 and fields generated by the RF power (RF signal) delivered to the support base 107 and/or bias electrode 104. In some aspects, the RF signal may be generated by the waveform generator assembly 150. The processing volume 129 is fluidly coupled to one or more dedicated vacuum pumps through a vacuum outlet 120, which maintain the processing volume 129 at sub-atmospheric pressure conditions and evacuate processing and/or other gases, therefrom. In some embodiments, the substrate support assembly 136, disposed in the processing volume 129, is disposed on a support shaft 138 that is grounded and extends through the chamber base 124. The waveform generator assembly 150 may include an RF generator 506, as shown in FIG. 5. As shown in FIG. 5, the RF generator 506 may be implemented using an RF signal source 580 and a RF matching network 582, in some embodiments. In some embodiments, as discussed further below, the RF generator 506 is configured to deliver an RF signal having a frequency that is greater than 40 MHZ, such as between about 40 MHz and about 200 MHz.

The substrate support assembly 136, as briefly discussed above, generally includes the substrate support 105 (e.g., ESC substrate support) and support base 107. In some embodiments, the substrate support assembly 136 can additionally include an insulator plate 111 and a ground plate 112, as is discussed further below. The support base 107 is electrically isolated from the chamber base 124 by the insulator plate 111, and the ground plate 112 is interposed between the insulator plate 111 and the chamber base 124. The substrate support 105 is thermally coupled to and disposed on the support base 107. In some embodiments, the support base 107 is configured to regulate the temperature of the substrate support 105, and the substrate 103 disposed on the substrate support 105, during substrate processing. In some embodiments, the support base 107 includes one or more cooling channels (not shown) disposed therein that are fluidly coupled to, and in fluid communication with, a coolant source (not shown), such as a refrigerant source or water source having a relatively high electrical resistance. In some embodiments, the substrate support 105 includes a heater (not shown), such as a resistive heating element embedded in the dielectric material thereof. Herein, the support base 107 is formed of a corrosion-resistant thermally conductive material, such as a corrosion-resistant metal, for example aluminum, an aluminum alloy, or a stainless steel and is coupled to the substrate support with an adhesive or by mechanical means.

Typically, the substrate support 105 is formed of a dielectric material, such as a bulk sintered ceramic material, such as a corrosion-resistant metal oxide or metal nitride material, for example, aluminum oxide (Al₂O₃), aluminum nitride (AlN), titanium oxide (TiO), titanium nitride (TiN), yttrium oxide (Y₂O₃), mixtures thereof, or combinations thereof. In embodiments herein, the substrate support 105 further includes the bias electrode 104 embedded in the dielectric material thereof.

In one configuration, the bias electrode 104 is a chucking pole used to secure (i.e., chuck) the substrate 103 to the substrate supporting surface 105A of the substrate support 105 and to bias the substrate 103 with respect to the processing plasma 101 using one or more of the pulsed-voltage biasing schemes described herein. Typically, the bias electrode 104 is formed of one or more electrically conductive parts, such as one or more metal meshes, foils, plates, or combinations thereof.

In some embodiments, the bias electrode 104 is electrically coupled to a clamping network, which provides a chucking voltage thereto, such as static DC voltage between about −5000 V and about 5000 V, using an electrical conductor, such as the coaxial power delivery line 106 (e.g., a coaxial cable). As will be discussed further below, the clamping network includes a DC power supply 155 (e.g., a high voltage DC (HVDC) supply) and a filter 151 (e.g., a low-pass filter).

The substrate support assembly 136 may further include the edge control electrode 115 that is positioned below the edge ring 114 and surrounds the bias electrode 104 and/or is disposed a distance from a center of the bias electrode 104. In general, for a processing chamber 100 that is configured to process circular substrates, the edge control electrode 115 is annular in shape, is made from a conductive material, and is configured to surround at least a portion of the bias electrode 104. In some embodiments, such as shown in FIG. 1, the edge control electrode 115 is positioned within a region of the substrate support 105. In some embodiments, as illustrated in FIG. 1, the edge control electrode 115 includes a conductive mesh, foil, and/or plate that is disposed a similar distance (i.e., Z-direction) from the substrate supporting surface 105A of the substrate support 105 as the bias electrode 104.

The edge control electrode 115 can be biased by use of a waveform generator assembly that is different from the waveform generator assembly 150 that is used to bias the bias electrode 104. In some embodiments, the edge control electrode 115 can be biased by use of a waveform generator assembly 150 that is also used to bias the bias electrode 104 by splitting part of the power to the edge control electrode 115. In one configuration, a first waveform generator assembly 150 of the first source assembly 196 is configured to bias the bias electrode 104, and a second waveform generator assembly 150 of a second source assembly 197 is configured to bias the edge control electrode 115.

A power delivery line 157 electrically connects the output of the waveform generator assembly 150 of the first source assembly 196 to the bias electrode 104. While the discussion below primarily discusses the power delivery line 157 of the first source assembly 196, which is used to couple a waveform generator assembly 150 to the bias electrode 104, the power delivery line 158 of the second source assembly 197, which couples a waveform generator assembly 150 to the edge control electrode 115, will include the same or similar components. The electrical conductor(s) within the various parts of the power delivery line 157 may include: (a) one or a combination of coaxial cables, such as a flexible coaxial cable that is connected in series with a rigid coaxial cable, (b) an insulated high-voltage corona-resistant hookup wire, (c) a bare wire, (d) a metal rod, (e) an electrical connector, or (f) any combination of electrical elements in (a)-(e).

In some embodiments, the processing chamber 100 further includes the quartz pipe 110, or collar, that at least partially circumscribes portions of the substrate support assembly 136 to prevent the substrate support 105 and/or the support base 107 from contact with corrosive processing gases or plasma, cleaning gases or plasma, or byproducts thereof. Typically, the quartz pipe 110, the insulator plate 111, and the ground plate 112 are circumscribed by a liner 108. In some embodiments, a plasma screen 109 is positioned between the cathode liner 108 and the sidewalls 122 to prevent plasma from forming in a volume underneath the plasma screen 109 between the liner 108 and the one or more sidewalls 122.

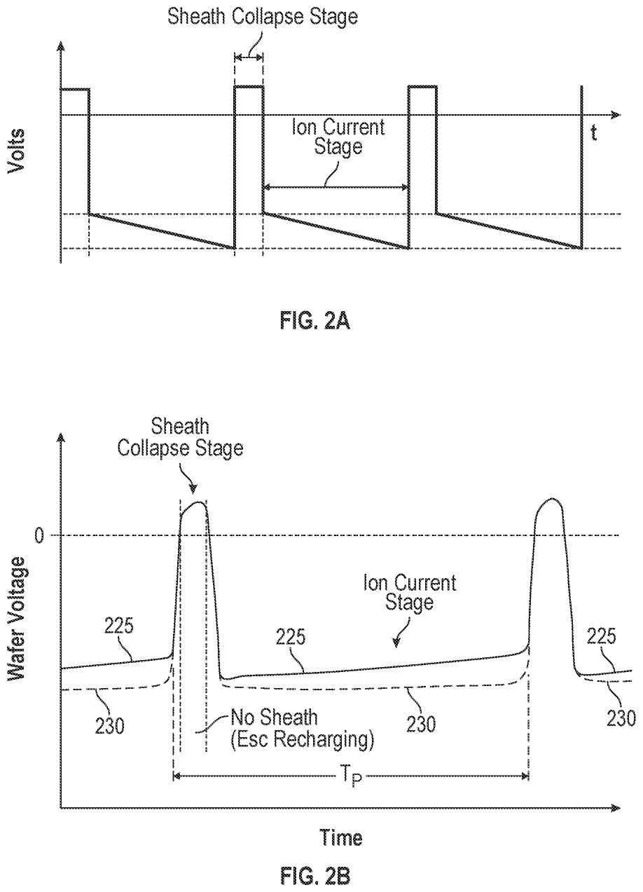

FIG. 2A shows a voltage waveform that may be established at an electrode of a processing chamber. FIG. 2B illustrates an example of different types of voltage waveforms 225 and 230 established at a substrate due to different voltage waveforms, similar to the voltage waveform shown in FIG. 2A, that are separately established at an electrode within the processing chamber. The waveforms include two stages: an ion current stage and a sheath collapse stage, as shown. At the beginning of the ion current stage, a drop of substrate voltage creates a high voltage sheath above the substrate, accelerating positive ions to the substrate. The positive ions that bombard the surface of the substrate during the ion current stage deposit a positive charge on the substrate surface, which if uncompensated for causes a gradually increase the substrate voltage positively during the ion current stage, as illustrated by voltage waveform 225 in FIG. 2B. However, the uncontrolled accumulation of positive charge on the substrate surface undesirably gradually discharges the sheath and chuck capacitors, slowly decreasing the sheath voltage drop and bringing the substrate potential closer to zero, as illustrated by voltage waveform 225. The accumulation of positive charge results in the voltage droop in the voltage waveform established at the substrate (FIG. 2B). However, a voltage waveform that is established at the electrode that has a negative slope during the ion current stage, as shown in FIG. 2A, can be generated so as to establish a square shaped region (e.g., near zero slope) for an established substrate voltage waveform, as shown by curve 230 in FIG. 2B. Implementing the slope in the waveform established at the electrode during the ion current stage may be referred to as current compensation. The voltage difference between the beginning and end of the ion current phase determines an ion energy distribution function (IEDF) width. The greater the voltage difference, the wider the IEDF width. To achieve monoenergetic ions and a narrower IEDF width, operations are performed to flatten the substrate voltage waveform in the ion current phase using current compensation. In some embodiments of the present disclosure, a RF signal is overlaid on the voltage waveform shown in FIG. 2A.

### Generation Technique for Waveform Generation

Certain embodiments of the present are generally directed to techniques for waveform generation that facilitate plasma processing of a substrate using simultaneous plasma generation and ion energy distribution (IED) control while reducing undesirable IED bowing profiles formed in the etched high aspect-ratio features. For example, a pulsed voltage (PV) waveform may be generated with an RF signal overlaid on the PV waveform. In some embodiments, the generated waveform may also include a ramp signal to facilitate current compensation, as described herein.

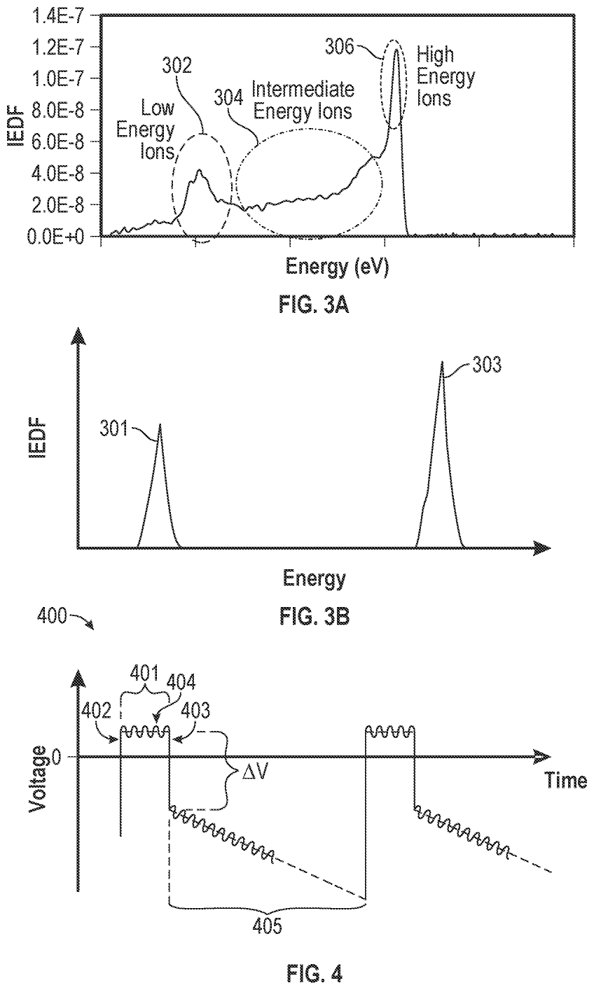

FIG. 3A illustrates a typical IED when using a single RF frequency excitation waveform. As shown, the IED has a bimodal shape having a high energy peak 306, a low energy peak 302, and intermediate energy ions (e.g., associated with an intermediate energy region 304). From the aspect of plasma etching processes, only the ions at or near the high energy peak have the energy and directionality to overcome the ion generated charging effect, created in the material that is being etched, and reach the bottom of a feature and enable etching reactions. Ions with intermediate energies are not beneficial for etch processes as they do not have the directionality and will tend to hit the sidewall of the feature, often resulting in an undesired IED bowing profile. Ions with low energy are important for etch processes as they clean the mask surface and maintain the shape of the mask layer, preventing hole clogging. Some embodiments of the present disclosure are directed to creating an energy profile having a high energy peak and a low energy peak, with little to no intermediate energy between the high and low energy peaks.

FIG. 3B is a graph illustrating an IED function (IEDF), in accordance with certain embodiments of the present disclosure. As shown, the IEDF includes a low energy peak 301 and a high energy peak 303. The energy associated with the low energy peak may be less than a few hundred eVs (e.g., less 1K eV), and the energy associated with the high energy peak may be a few hundred eVs to tens of thousands eVs, depending on aspect ratio of the feature to be formed in substrate. For instance, in some cases, the energy associated with the high energy peak may be between 4 k eV to 10 k eV. As shown, no ions exist (or at least fewer than conventional implementations) between the low energy peak 301 and the high energy peak 303. Some embodiments are directed to techniques for implementing the ion energy distribution shown in FIG. 3B using a waveform tailoring technique, as described in more detail herein.

FIG. 4 illustrates a waveform 400 generated using a waveform generator, in accordance with certain embodiments of the present disclosure. As shown, waveform 400 includes waveform regions 401 and 405. The waveform region 401 includes a direct current (DC) signal overlayed with a RF signal 404, and the waveform region 405 includes a voltage ramp (e.g., for current compensation) overlaid with the RF signal 404.

The RF signal 404 sustains the plasma in the chamber and produces the low energy peak 301 described with respect to FIG. 3B. The RF signal 404 may have a frequency between 40 MHz to 200 MHz, in some embodiments. The frequency of the RF signal 404 may be higher than the ion sheath transit frequency. In this case, the average ion transit time across the sheath thickness is longer than the period of the RF signal 404, resulting in the ions experiencing multiple cycles of RF signal 404 and obtaining the average energy associated with the multiple cycles to create the low energy peak 301. Therefore, ions are accelerated by the average sheath potential caused by the RF signal 404 such that a single ion energy peak is achieved. The high-frequency RF excitation produces ions with a mono energy peak. In other words, ions traveling across the sheath experience the average sheath potential driven by the RF signal 404, creating a single ion energy peak instead of a continuous energy distribution.

During a portion of a pulse waveform cycle, plasma bulk electrons are attracted to the surface of the substrate (e.g., substrate 103) due to the rising edge 402 of the pulse step. However, the plasma bulk electrons may be unable to establish a negative DC sheath potential to produce the higher energy peak 303. The substrate surface and the electrode (e.g., support base 107) form a capacitive element (e.g., referred to as an electrostatic chuck capacitor (C_{esc})), which, in some embodiments, includes the dielectric material layer of the substrate support 105 disposed between the bias electrode 104 and the substrate supporting surface 105A, as shown in FIG. 1. There is an equal amount of positive charge on the electrode (e.g., as compared to the negative charge on the substrate) to cancel the field generated by the plasma bulk electrons. At the falling edge 403 of the waveform 400, the ions are neutralized by the electrons due to the application of the waveform to the electrode. Therefore, a negative DC sheath potential is established on the substrate surface. This is the origin of the higher energy peak 303. The DC sheath potential (Vdc), or the higher ion energy can be approximated using the magnitude of the falling edge (ΔV) and the ratio between C_{esc} and sheath capacitance (Cₛₕₑₐₜₕ) based on the equation:

$$Vdc = \frac{ΔV \times Cesc}{Cesc + Csheath}$$

Thus, the waveform region 401 serves to sustain the plasma (e.g., while producing the lower energy peak 301) in the chamber and establish a DC sheath potential for the higher energy peak 303.

As incoming ions neutralize the electrons on the substrate surface, the DC sheath potential decreases if there is no means of compensation. Consequently, ions incident onto the substrate will not be monoenergetic. In some embodiments, a voltage ramp is implemented during waveform region 405 to supply an increasing amount of electrons to the electrode to cancel the otherwise increasing field caused by the positive charges due to the incoming ions, thereby maintaining constant sheath potential (mono-energy peak). A DC supply current for implementing the ramp may be controlled to equalize and compensate for the ion current provided during the ion current stage. The ion current (Iᵢₒₙ) can be calibrated by using ion energy diagnostics or calculated by sampling the electrode voltage (V0) (e.g., to calculate time derivative of V0) and the value of the sheath potential, based on equation:

$${I}_{ion} = Csheath \frac{dV 0}{dt}$$

As shown, the RF signal 404 may also be overlaid on the ramp signal during region 405 to continue sustaining the plasma (e.g., while producing the lower energy peak 301) in the chamber and establishing a DC sheath potential for the higher energy peak 303.

FIG. 5 illustrates an example implementation of a waveform generator 500 for biasing a substrate to achieve IED control, in accordance with certain embodiments of the present disclosure. The waveform generator 500 may be used to implement the waveform generator assembly 150, as described with respect to FIG. 1. As shown, the waveform generator 500 may generate the waveform 400 described with respect to FIG. 4.

The waveform generator 500 includes a main voltage source 502 (e.g., a DC voltage source) for implementing the positive voltage during waveform region 401, a current source 505 for implementing the ramp voltage during waveform region 405, and an RF generator 506 (also referred to as an RF signal generator) for providing the RF signal 404. The waveform generator 500 generates the waveform 400 at output node 504. The output node 504 may be coupled to the bias electrode 104 in the substrate support 105 (e.g., ceramic puck) or the support base 107. If the output node 504 is coupled to the support base 107, the total capacitance (e.g., 1/Cₜₒₜₐₗ=1/C_{esc}+1/C_{SB}, where C_{SB} is the capacitance of the dielectric layer disposed between the support base 107 and the bias electrode 104) between the output node 504 and the substrate 103 will be greater than if the output node 504 is coupled to the bias electrode 104 (e.g., C_{esc}). The greater capacitance may result in a lower voltage drop across C_{esc} and more voltage drop on the sheath.

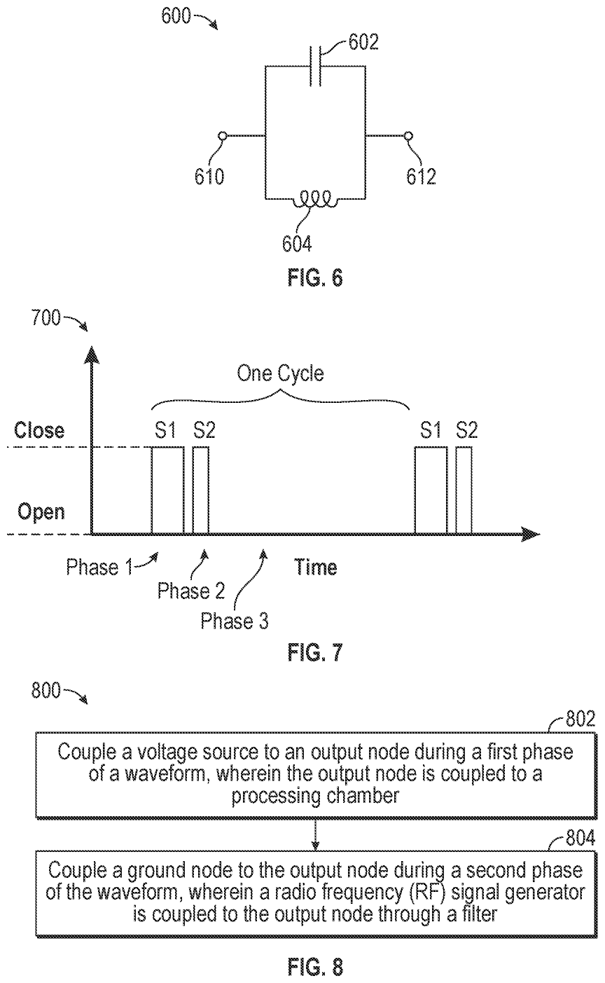

As shown, a switch 520 (e.g., a high voltage solid-state relay) may be coupled between the main voltage source 502 and the output node 504, and a switch 522 (e.g., a high voltage solid-state relay) may be coupled between a ground node 508 and the output node 504. As shown, RF filter 540 may be implemented in a path between the voltage source 502 and the switch 520, an RF filter 542 may be implemented in a path between the ground node 508 and switch 522, and an RF filter 544 may be implemented between the current source 505 and the output node 504. The RF filters 540, 542, 544 may be implemented as low-pass filters configured to block the RF signal(s) provided from the RF generator 506. The voltage source 502 and current source 505 are protected by respective RF filters 540, 544 from the output of the RF generator 506. In other words, the RF filters 540, 544 are configured to block the high-frequency RF signals provided from the RF generator 506. The ground node 508 is isolated from the RF generator 506 by the RF filter 542 (e.g., a low pass filter) when switch 522 is closed. In some embodiments, each of the RF filters 540, 542, 544 may be implemented as a parallel LC topology, as shown in FIG. 6.

FIG. 6 illustrates a parallel LC filter topology 600 having a capacitive element 602 and an inductive element 604. As shown, the capacitive element 602 may be coupled in parallel to the inductive element 604 and between nodes 610, 612. Each of the RF filters 540, 542, 544 may be implemented using the parallel LC filter topology 600. For instance, for RF filter 542, the node 610 may be coupled to the ground node 508 and the node 612 may be coupled to switch 522. As one example, for a 40 MHz RF signal, the capacitive element 602 may be 100 pico-farads (pF) and the inductive element 604 may be 158 nano-henries (nH) to block the 40 MHz RF signal. In other words, the LC filter topology 600 is a resonant circuit that effectively acts as an open circuit for a 40 MHz signal, isolating the voltage source 502, ground node 508, or current source 505 from the 40 MHz RF signal.

FIG. 7 is a timing diagram 700 illustrating states of switch 520 (labeled as “S1”) and switch 522 (labeled as “S2”), in accordance with certain embodiments of the present disclosure. As shown, switches 520, 522 are not closed simultaneously to avoid electrically shorting the voltage source 502 to the ground node 508. In some embodiments, during phase 1 of a waveform cycle (e.g., a cycle of waveform 400), switch 520 may be closed to produce the rising edge 402 as shown in FIG. 4. Switch 520 may be closed for a period ranging from 20 ns to 2000 ns to allow enough number of electrons to be collected at the substrate surface. After the period associated with waveform region 401, the switch 520 may be opened and switch 522 may be closed to produce the falling edge 403 during phase 2 of the waveform cycle. After opening the switch S1, switch S2 may be closed for a time period ranging from 10 ns to 100 ns.

In some embodiments, during phase 1 while switch S1 is closed, a positive charge accumulates on the substrate 103 shown in FIG. 1. The voltage on the substrate 103 cannot change instantaneously due to capacitive effects. Thus, during phase 2, once switch S1 is opened and switch S2 is closed, the voltage at the output node 504 (e.g., at electrode 104 shown in FIG. 1) drops from a positive voltage to a negative voltage as shown in FIG. 4. It is believed that the drop from the positive voltage to the negative voltage is due to a negative charge forming on the electrode 104 to counteract the positive charge on the substrate 104. In other words, the positive charge on the substrate 103 attracts electrons to the electrode 104, causing the drop to the negative voltage at the output node 504 upon closure of switch S2.

During phase 3 of the waveform cycle, both switches 520, 522 remain open. As shown in FIG. 5, RF generator 506 and the current source 505 may be connected to the output node 504 (e.g., to the chamber) at all times. In some embodiments, a high-pass filter 546 may be coupled between the RF generator 506 and the output node 504. The high-pass filter 546 isolates the RF generator from the DC components at the output node 504 (e.g., caused by the current source 505, voltage source 502 when switch 520 is closed, or the ground node 508 when switch 522 is closed). The high-pass filter 546 may be implemented as an alternating current (AC) blocking capacitor in some embodiments.

In some embodiments, an impedance 570 may be coupled between the output of the current source 505 and the ground node to shunt the output current from the current source 505 when the switch 520 closes. In other words, an abrupt impedance change may occur due to the coupling of the voltage source 502 to the output node 504. The impedance 570 provides a flow path for the current from the current source 505 to ground once the switch 520 closes, allowing a gradual decrease of the current from current source 505 after the rising edge 402. As shown, the impedance 570 may be implemented using an inductor-resistor (RL) circuit having an inductive element 574 and a resistive element 572. When using a 40 MHz RF signal, the impedance of the inductive element may be 2 microhenries (μH) and the resistance of the resistive element 572 may be 100 ohms.

The embodiments of the present disclosure provide a process-favorable dual-peak IED and a method to achieve such IED on substrate surface for plasma processing chambers with simultaneous plasma excitation and sustainment. One advantage of embodiments of the present disclosure as compared to traditional ion energy control techniques is the simultaneous plasma generation and IED control. After one PV waveform cycle has been completed, a plurality of additional PV waveform cycles will be serially repeated multiple times, as illustrated in FIG. 4 by the partial illustration of the repeated second voltage waveform cycle. In some embodiments, voltage waveform established at the electrode has an on-time, which is defined as the ratio of the ion current time period (e.g., length of waveform region 405) and the waveform period T_{P} (e.g., length of waveform region 401+length of waveform region 405), is greater than 50%, or greater than 70%, such as between 80% and 95%. In some embodiments, a PV waveform that has a waveform cycle has a period T_{P} of about 2.5 μs is serially repeated within a PV waveform burst that has a burst period that is between about 100 microseconds (us) and about 10 milliseconds (ms). The burst of PV waveforms can have a burst duty cycle that is between about 5%-100%, such as between about 50% and about 95%, wherein the duty cycle is the ratio of the burst period divided by the burst period plus a non-burst period (i.e., no PV waveforms are generated) that separates the burst periods.

FIG. 8 is a process flow diagram illustrating a method 800 for waveform generation. The method 800 may be performed by a waveform generation system including a waveform generator, such as the waveform generator 500, and/or a system controller such as the system controller 126.

At activity 802, the waveform generation system couples (e.g., by closing switch 520) a voltage source (e.g., voltage source 502) to an output node (e.g., output node 504) during a first phase (e.g., phase 1 shown in FIG. 7) of a waveform (e.g., waveform 400). The output node may be coupled to an electrode disposed within a processing chamber (e.g., processing chamber 100). For example, the output node may be coupled to electrode 104 or support base 107.

At activity 804, waveform generation system couples (e.g., by closing switch 522) a ground node (e.g., ground node 508) to the output node during a second phase (e.g., phase 2 shown in FIG. 7) of the waveform. In some embodiments, a RF signal generator (e.g., RF generator 506) is coupled to the output node through a filter (e.g., filter 546) during the first phase. The RF signal generator may be coupled to the output node during the first phase, the second phase, and a third phase (e.g., phase 3 shown in FIG. 7) of the waveform. The voltage source and the ground node are decoupled (e.g., by opening switches 520, 522) from the output node during the third phase. In some embodiments, the voltage source is coupled to the output node through a filter (e.g., filter 540), and the ground node is coupled to the output node through a filter (e.g., filter 542).

In some embodiments, a current source (e.g., current source 505) is coupled to the output node during a third phase of the waveform, the voltage source and the ground node being decoupled from the output node during the third phase. The current source may be coupled to the output node through a filter (e.g., filter 544).

The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object.

While the foregoing is directed to embodiments of the present disclosure, other and further embodiments of the disclosure may be devised without departing from the basic scope thereof, and the scope thereof is determined by the claims that follow.

1. A waveform generator, comprising:
an output node configured to be coupled to an electrical component within a processing chamber;
a voltage source selectively coupled to the output node;
a ground node selectively coupled to the output node; and
a radio frequency (RF) signal generator coupled to the output node and isolated from the voltage source and the ground node.

2. The waveform generator of claim 1, wherein:
the voltage source is selectively coupled to the output node via a first switch; and
the ground node is selectively coupled to the output node via a second switch.

3. The waveform generator of claim 2, wherein:
the first switch is configured to couple the voltage source to the output node during a first phase of a pulsed waveform; and
the second switch is configured to couple the ground node to the output node during a second phase of a pulsed waveform.

4. The waveform generator of claim 1, further comprising:
a current source coupled to the output node and isolated from the RF signal generator.

5. The waveform generator of claim 4, further comprising:
a filter configured to isolate the RF signal generator from at least one of the voltage source, the ground node, and the current source.

6. The waveform generator of claim 5, wherein:
the filter comprises a low-pass filter.

7. The waveform generator of claim 6, wherein:
the filter is coupled between the voltage source and the output node.

8. The waveform generator of claim 6, wherein:
the filter is coupled between the ground node and the output node.

9. The waveform generator of claim 6, wherein:
the filter is coupled between the current source and the output node.

10. The waveform generator of claim 5, wherein:
the filter comprises a high-pass filter.

11. The waveform generator of claim 10, wherein:
the filter is coupled between the RF signal generator and the output node.

12. The waveform generator of claim 4, further comprising:
an impedance coupled between the current source and the ground node.

13. The waveform generator of claim 12, wherein:
the impedance comprises an inductor-resistance circuit for shunting the current source.

14. The waveform generator of claim 4, the waveform generator is configured to generate a pulsed waveform by:
coupling the voltage source to the output node during a first phase of the pulsed waveform;
coupling the ground node to the output node during a second phase of the pulsed waveform;
coupling the current source to the output node during a third phase of the pulsed waveform; and
coupling the RF signal generator to the output node during at least one of the first phase, the second phase, and the third phase of the pulsed waveform.

15. A waveform generation system for a processing chamber, comprising:
a first waveform generator coupled to a first electrode within the processing chamber; and
a second waveform generator coupled to a second electrode within the processing chamber, wherein each of the first waveform generator and the second waveform generator comprise:
an output node configured to be coupled to an electrical component within a processing chamber;
a voltage source selectively coupled to the output node;
a ground node selectively coupled to the output node; and
a radio frequency (RF) signal generator coupled to the output node and isolated from the voltage source and the ground node.

16. The waveform generation system of claim 15, wherein each of the first waveform generator and the second waveform generator further comprise:
a current source coupled to the output node and isolated from the RF signal generator.

17. The waveform generation system of claim 16, further comprising:
a filter configured to isolate the RF signal generator from at least one of the voltage source, the ground node, and the current source.

18. The waveform generation system of claim 15, wherein:
the first electrode comprises a substrate biasing electrode disposed in a substrate support; and
the second electrode comprises an edge control electrode disposed radially outward of the first electrode in the substrate support.

19. A method for waveform generation, comprising:
coupling a voltage source to an output node during a first phase of a waveform, wherein the output node is coupled to an electrical component disposed within a processing chamber;
coupling a ground node to the output node during a second phase of the waveform; and
coupling a radio frequency (RF) signal generator to the output node during at least one of the first phase and the second phase of the waveform, wherein the RF signal generator is isolated from the voltage source and the ground node when coupled to the output node.

20. The method of claim 19, further comprising:
coupling the current source to the output node during a third phase of the pulsed waveform, wherein the current source is isolated from the RF signal generator when coupled to the output node.
